(19) United States
(12) Patent Application Publication
(10) Pub. No.: US 2021/0065627 A1
(43) Pub. Date: Mar. 4, 2021

(54) Control method for OLED touch panel and related touch and OLED driver

(71) Applicant: NOVATEK Microelectronics Corp., Hsin-Chu (TW)

(72) Inventor: Chun-Yi Chou, Hsinchu City (TW)

(21) Appl. No.: 16/882,540

(22) Filed: May 24, 2020

Related U.S. Application Data
(60) Provisional application No. 62/891,971, filed on Aug. 27, 2019.

(51) Int. Cl. G09G 3/3258; G06F 3/041; G06F 3/044; G09G 3/3266; G09G 3/3275

(52) U.S. Cl. CPC G09G 3/3258; G06F 3/0416; G09G 3/3275; G09G 3/3266; G06F 3/0443

(57) ABSTRACT

The present invention provides a control method for a touch and organic light-emitting diode (OLED) driver, for controlling an OLED touch panel. The OLED touch panel has a dark screen mode and a normal display mode, and includes a cathode layer of OLEDs. The control method includes a plurality of steps, and the steps include applying a first load-free driving (LFD) signal to the cathode layer or controlling the cathode layer to be floating during a touch sensing period in the dark screen mode; and applying a constant voltage to the cathode layer in the normal display mode.

### CROSS REFERENCE TO RELATED APPLICATIONS

This application claims the benefit of U.S. Provisional Application No. 62/891,971, filed on Aug. 27, 2019, the contents of which are incorporated herein by reference.

### BACKGROUND OF THE INVENTION

### 1. Field of the Invention

The present invention relates to a control method for an organic light-emitting diode (OLED) panel, and more particularly, to a control method for an OLED touch panel and a related touch and OLED driver.

### 2. Description of the Prior Art

Please refer to FIG. 1, which is a schematic diagram of a general organic light-emitting diode (OLED) panel 10. FIG. 1 briefly shows the side view of the OLED panel 10 having a top emission structure. As shown in FIG. 1, the OLED panel 10 includes a substrate 100, an OLED layer 102, an encapsulation layer 104 and a polarizer 106. The OLED panel 10 may further include a top substrate (not illustrated) disposed on the polarizer 106. The substrate 100 may be a glass substrate or a flexible substrate, and there may be thin-film transistors (TFTs) disposed on the substrate 100. A driving TFT and an OLED (which may be disposed on the OLED layer 102) in each display pixel may cooperate to control the light emission of each display pixel. The encapsulation layer 104 and the top substrate may be configured to protect the inside circuitry and isolate the circuitry from the air, to prevent the circuit elements and wires from being oxidized. The polarizer is configured to filter and guide the lights, allowing each pixel to display a specific color.

FIG. 2 illustrates the structure of an exemplary OLED touch panel 20, which may be a general OLED panel implemented with an on-cell touch sensor. FIG. 2 shows the side view of the structure of an on-cell flexible panel. As shown in FIG. 2, the OLED touch panel 20 includes a substrate 200, an OLED layer 202, an encapsulation layer 204, a touch sensor layer 205, a polarizer 206 and a cover window 208. As for the flexible structure, the substrate 200 may be implemented with polyimide (PI), and the TFTs are disposed on the PI substrate 200. The touch sensor layer 205 may include touch sensing electrodes plated on a film. In order not to affect the display images, the touch sensing electrodes may be implemented with a transparent material such as an indium tin oxide (ITO). In addition, the implementations and operations of the OLED layer 202, the encapsulation layer 204 and the polarizer 206 are similar to those of the OLED layer 102, the encapsulation layer 104 and the polarizer 106 shown in FIG. 1. The cover window 208 may be regarded as the top substrate, which has lattices or windows that allow light emission for displaying desired images. In this example, the touch sensor layer 205 may be disposed on the encapsulation layer 204, and the polarizer 206 and the cover window 208 may be disposed on the touch sensor layer 205, e.g., glued via an optically clear adhesive (OCA).

Due to the trends of light and thin of the panel size, the touch sensing electrodes may be integrated into the encapsulation layer of the panel. FIG. 3 illustrates the structure of an exemplary OLED touch panel 30 where the touch sensor is integrated with the encapsulation layer. The OLED touch panel 30 includes a substrate 300, an OLED layer 302, an encapsulation layer 304 with touch sensor, a polarizer 306 and a cover window 308. The implementations and operations of the substrate 300, the OLED layer 302, the polarizer 306 and the cover window 308 are similar to those of the substrate 200, the OLED layer 202, the polarizer 206 and the cover window 208 shown in FIG. 2. The difference between the OLED touch panel 30 and the OLED touch panel 20 is that, in the OLED touch panel 30, the touch sensor is deployed in an in-line process to be integrated into the encapsulation layer 304. In detail, the encapsulation materials in the encapsulation layer 304 may include nonconductive materials such as organic materials and silicon oxide, and these materials are superposed layer after layer to form the entire encapsulation layer 304. The touch sensor, which may include metal meshes that construct the pattern of touch sensing electrodes, may be plated on one or more sub-layers of the encapsulation layer 304, so as to be integrated into the encapsulation layer 304 in the fabrication process.

Please note that the thickness of the encapsulation layer 304 integrating with the touch sensor is quite thin. For example, the vertical distance from the top of the encapsulation layer 304 to the substrate 300 may be approximately equal to 10 micrometers (μm), as shown in FIG. 3. With the extremely short distance, it is easy to route the touch control lines from the touch sensor to the touch control integrated circuit (IC) 310 (which is disposed on the substrate 300) at the border of the panel. Also, the display control lines (such as gate lines or data lines) may also be easily routed to the display control IC 320 (which is disposed on the substrate 300) from the OLED layer 302 through the connecting lines at the border of the panel. In such a situation, the display control IC 320 may easily be integrated with the touch control IC 310, to realize the touch and display driver integration (TDDI). In comparison, as shown in FIG. 2, in the OLED touch panel 20, the thickness of the touch sensor layer 205 including the film may be approximately 100 μm, such that it requires a larger border width to route the touch control lines to the touch control IC 210. If the touch control IC 210 needs to be integrated with the display control IC 220 on the substrate 200, the routing distance will become larger and a wider border may be needed. Therefore, compared to the conventional OLED touch panel 20, the touch-sensor-integrated structure of the OLED touch panel 30 is more feasible for small-size panel applications such as in a mobile phone or wearable device.

However, in the OLED touch panel 30, the touch sensor is extremely close to the cathode electrode of the OLED layer 302, causing a large capacitive loading on the touch sensor. In an example, the capacitive loading may be up to 500-1000 picofarads (pF). Also, the capacitive loading between the touch sensor and the data lines and gate lines of the panel may become larger due to the short distance therebetween. The large capacitive loading may generate a large burden on touch driving and sensing, such that the touch driving/sensing operations require more power consumption to overcome the loading. The power consumption becomes larger with the increasing of panel size and resolution since there may be more touch sensor traces on a large-scale panel.

Note that the touch sensing functions of a touch panel may be enabled no matter in display or in dark screen. For example, a mobile phone is usually equipped with a touch wake-up function that may detect a specific touch gesture in the dark screen mode to wake up the device. In the dark screen mode, it is required to minimize power consumption to let the standby time as long as possible. However, the touch detection, which may be performed periodically even if no touch appears on the panel, may consume non-ignorable power under large capacitive loading. The additional power consumption of touch detection resulted from the capacitive loading may reduce the standby time of the electronic device. Thus, there is a need for improvement over the prior art.

### SUMMARY OF THE INVENTION

It is therefore an objective of the present invention to provide a control method for an organic light-emitting diode (OLED) touch panel, in order to solve the abovementioned problems.

An embodiment of the present invention discloses a control method for a touch and OLED driver, for controlling an OLED touch panel. The OLED touch panel has a dark screen mode and a normal display mode, and comprises a cathode layer of OLEDs. The control method comprises a plurality of steps, and the steps include applying a first load-free driving (LFD) signal to the cathode layer or controlling the cathode layer to be floating during a touch sensing period in the dark screen mode, and applying a constant voltage to the cathode layer in the normal display mode.

Another embodiment of the present invention discloses a touch and OLED driver. The touch and OLED driver is configured to control an OLED touch panel. The OLED touch panel has a dark screen mode and a normal display mode, and comprises a cathode layer of OLEDs. The touch and OLED driver is configured to apply a first LFD signal to the cathode layer or control the cathode layer to be floating during a touch sensing period in the dark screen mode, and apply a constant voltage to the cathode layer in the normal display mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a general OLED panel.

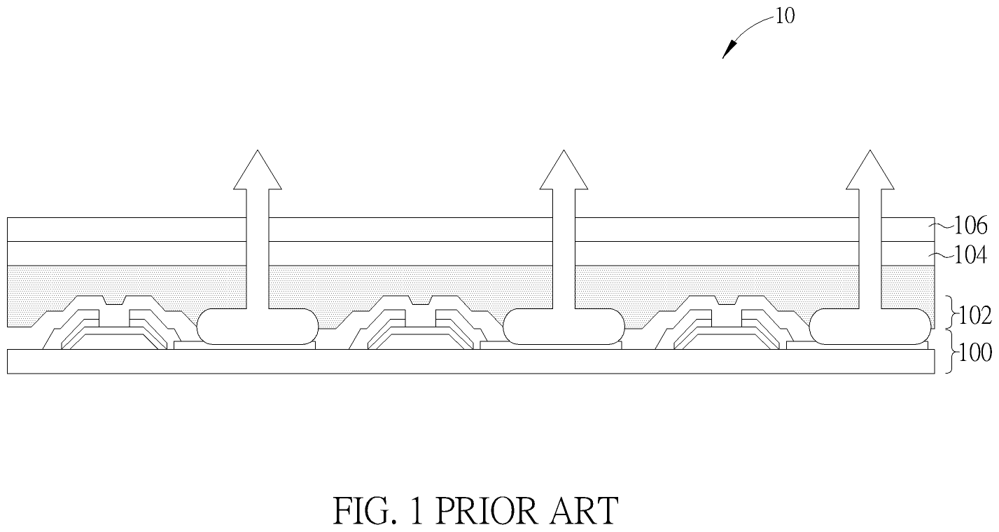

FIG. 2 illustrates the structure of an exemplary OLED touch panel.

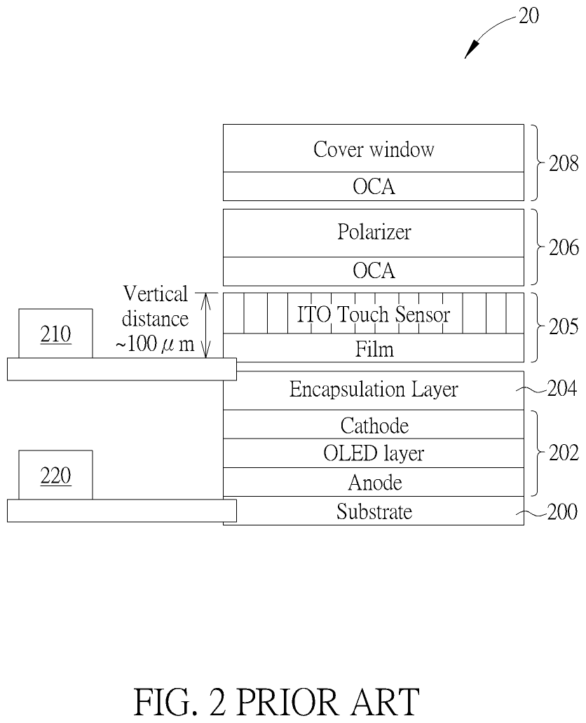

FIG. 3 illustrates the structure of an exemplary OLED touch panel where the touch sensor is integrated with the encapsulation layer.

FIG. 4 is a schematic diagram of a touch panel according to an embodiment of the present invention.

FIG. 5 is a schematic diagram of a display system according to an embodiment of the present invention.

FIG. 6 is a schematic diagram of the display system operating in a low power mode.

FIG. 7 is a flowchart of a control process according to an embodiment of the present invention.

FIG. 8 is an exemplary waveform diagram of related signals of the display system shown in FIG. 5.

FIG. 9 is a schematic diagram of the display system operating during touch sensing periods in a dark screen mode.

### DETAILED DESCRIPTION

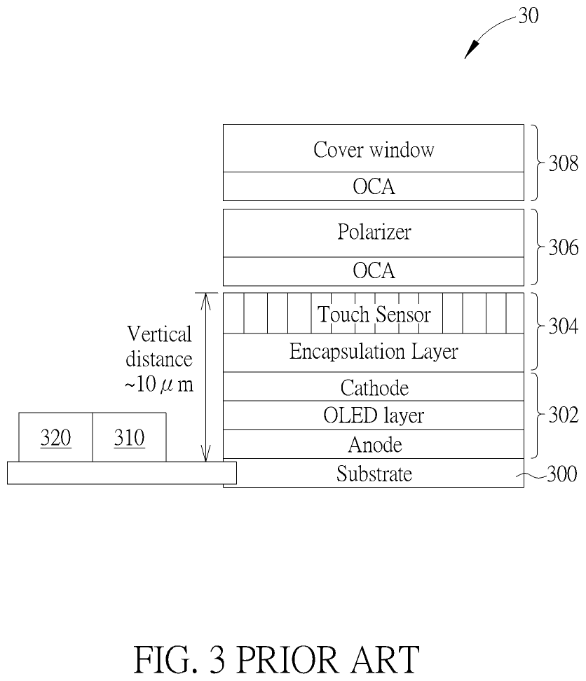

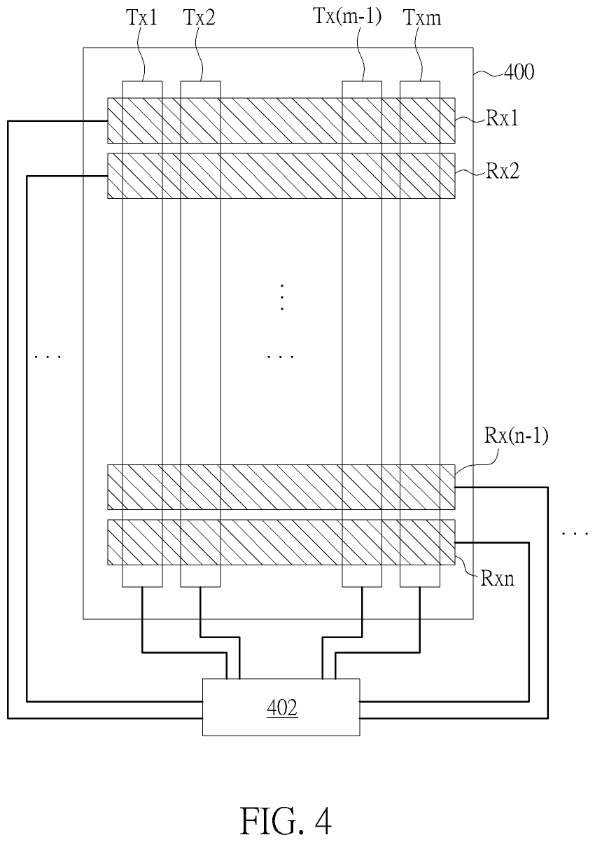

Please refer to FIG. 4, which is a schematic diagram of a touch panel 400 according to an embodiment of the present invention. As shown in FIG. 4, the touch panel 400 includes a touch sensor having a plurality of touch sensing electrodes. In detail, the touch sensing electrodes may include a plurality of driving electrodes Tx1-Txm disposed in a layer and a plurality of sensing electrodes Rx1-Rxn disposed in another layer. The layers described herein may be the sub-layers included in the encapsulation layer 304 as shown in FIG. 3. The driving electrodes Tx1-Txm may be bar-shaped electrodes disposed toward the vertical direction and the sensing electrodes Rx1-Rxn may be bar-shaped electrodes disposed toward the horizontal direction. Each of the electrodes is connected to a touch controller 402, which may be implemented as an integrated circuit (IC) in a chip.

In order to perform touch detection, the touch controller 402 may send a touch driving signal, e.g., a square wave signal, to each of the driving electrodes Tx1-Txm. The touch controller 402 may include a receiver configured to receive touch sensing signals from the touch panel 400. In detail, when the touch driving signal is sent to the driving electrodes Tx1-Txm, the receiver may receive the touch sensing signals from the sensing electrodes Rx1-Rxn, so as to realize mutual capacitive touch sensing. In another embodiment, when the touch driving signal is sent to the driving electrodes Tx1-Txm, the receiver may receive the touch sensing signals from the same driving electrodes Tx1-Txm, so as to realize self-capacitive touch sensing. Alternatively, the touch driving signals may be sent to the electrodes Rx1-Rxn while the touch sensing signals may be received from the electrodes Tx1-Txm, which means that the electrodes Rx1-Rxn may operate as driving electrodes and the electrodes Tx1-Txm may operate as sensing electrodes. The received sensing signals may reflect capacitance variations on the driving electrodes and/or the sensing electrodes due to a touch gesture.

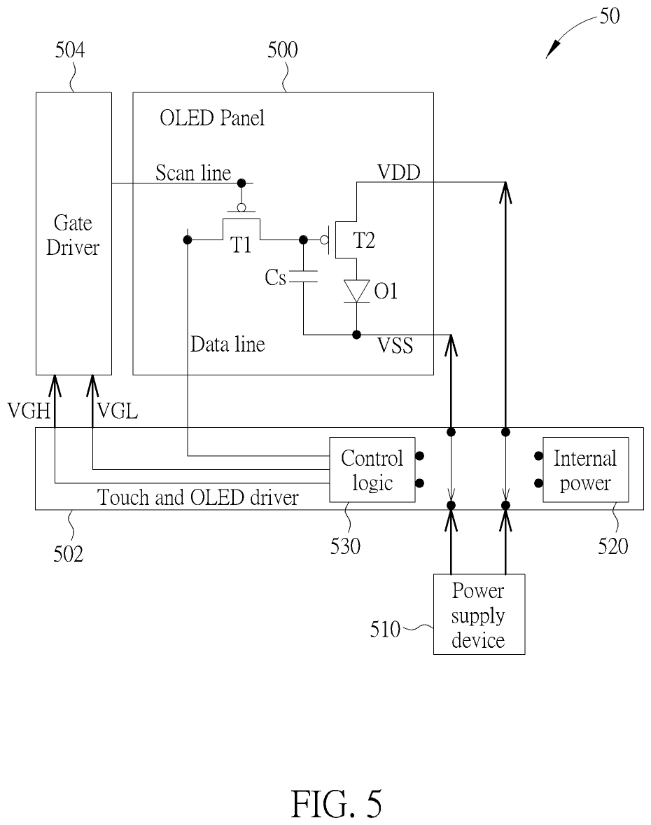

Please refer to FIG. 5, which is a schematic diagram of a display system 50 according to an embodiment of the present invention. As shown in FIG. 5, the display system 50 includes an organic light-emitting diode (OLED) panel 500, a touch and OLED driver 502, a gate driver 504 and a power supply device 510. The OLED panel 500 may be an active-matrix OLED (AMOLED) panel, which includes a plurality of display pixels arranged as an array. For the sake of simplicity, only one display pixel is illustrated in FIG. 5. The display pixel includes transistors (such as thin-film transistors (TFTs)) T1 and T2, a storage capacitor Cs and an OLED 01. The display pixel is capable of displaying a predetermined brightness by receiving display data from the data line, as being controlled by a scan signal forwarded through the scan line when the power supply voltages VDD and VSS are received. In an embodiment, the power supply voltage VDD may be a positive voltage between 4V and 5V, and the power supply voltage VSS may be a negative voltage between −3V and −1V. The touch and OLED driver 502 may adjust the actual power supply voltages VDD and/or VSS based on the total current consumption of the OLED panel 500. During the display operation of the pixel, the received display data may be stored in the storage capacitor Cs, and the display data may be converted into a current through the transistor T2. The current flowing through the OLED 01 controls the OLED 01 to emit light, and the light intensity corresponds to the current magnitude.

In the OLED panel 500, each display pixel has a similar structure as shown in FIG. 5. The cathode electrode of the OLED of each display pixel may be implemented as the cathode layer shown in FIG. 3 and commonly connected to the same power supply node. More specifically, these cathode electrodes may be commonly connected to the power supply device 510 for receiving the power supply voltage VSS.

Please continue to refer to FIG. 5. The touch and OLED driver 502 is configured to forward the display data to the display pixels of the OLED panel 500, and output gate control signals VGH and VGL to the gate driver 504. In an embodiment, the touch and OLED driver 502 may be a control IC capable of touch control and display control functions; that is, the touch and OLED driver 502 may include the touch controller 402 as shown in FIG. 4. The touch and OLED driver 502 may further include an internal power source 520 and control logic 530. The internal power source 520 is configured to supply power for internal use of the touch and OLED driver 502, and may also be configured to supply power for the OLED panel 500. The control logic 530 is configured to control the gate driver 504 and the display pixels of the OLED panel 500 by sending the gate control signals VGH and VGL and the display data voltages, to realize the display operations.

Upon receiving the gate control signals VGH and VGL, the gate driver 504 may control the display pixels to be turned on row by row with scan signals through the scan lines. The gate driver 504 may be, for example, integrated into the touch and OLED driver 502, or implemented on the substrate of the OLED panel 500 as a gate-on-array (GOA) structure. The power supply device 510 may be an external power source independent to the touch and OLED driver 502. In an embodiment, the power supply device 510 may be a DC-to-DC converter capable of supplying DC power for the OLED panel 500.

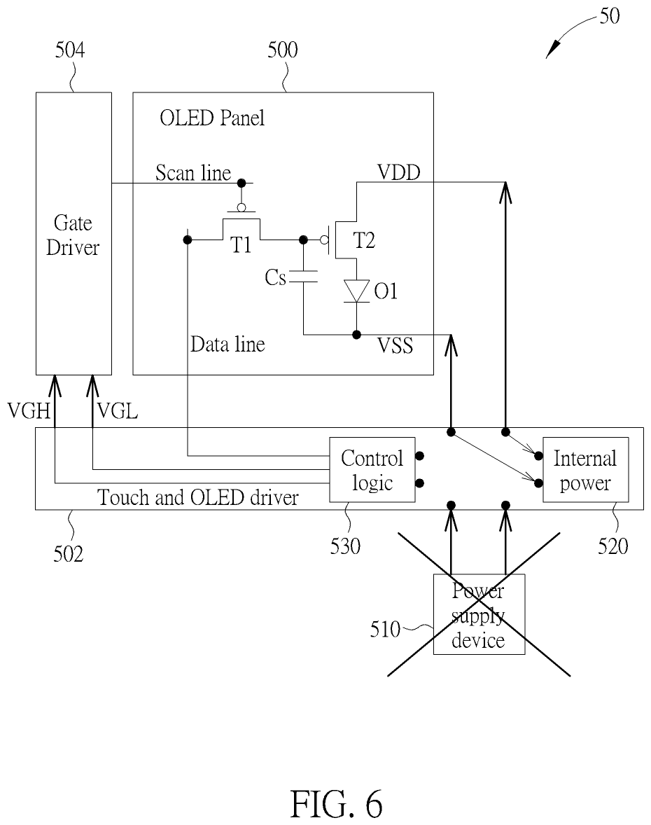

FIG. 5 shows a normal display mode, where the OLED panel 500 may display an image normally. Under the normal display mode, the transistor T2 and the OLED 01 are coupled to the power supply device 510, and thus the display pixels receive the power supply voltages VDD and VSS from the power supply device 510. FIG. 6 shows that the display system 50 operates in a low power mode such as an always on display (AOD) mode. Under the AOD mode, the OLED panel 500 may only show a small figure including user-defined information such as date, time, and/or power quantity in a small area; hence, the total currents and power required by the OLED panel 500 in the AOD mode may be much lower than those in the normal display mode. In such a situation, the power supply device 510 may be disabled, and the transistor T2 and the OLED 01 of the display pixels may be coupled to the internal power source 520 of the touch and OLED driver 502 rather than being coupled to the power supply device 510, so as to receive the power supply voltages VDD and VSS from the internal power source 520. This is because the efficiency of the power supply device 510, e.g., the DC-to-DC converter, may be poor under light load applications, and thus it is preferable to use a more appropriate power supply device such as a charge pump included in the touch and OLED driver 502 to supply power.

Therefore, no matter in the normal display mode or the AOD mode, the power nodes, especially the cathode layer, of the OLED panel 500 are coupled to a specific power supply device to receive DC power voltages. In addition to the normal display mode and the AOD mode, the OLED panel 500 may operate in a dark screen mode or black screen mode. Under the dark screen mode or black screen mode, no any image is displayed on the OLED panel 500; that is, the display function of the OLED panel 500 may be off. In such a situation, the display system 50 may be in a standby mode or idle mode. These operation modes are collectively referred to as the dark screen mode hereinafter. Note that in the dark screen mode, the touch and OLED driver 502 may still detect touch events for the touch wake-up function. In other words, the touch and OLED driver 502 may periodically send touch signals to the OLED panel 500, to detect whether there is a touch event and determine to wake up the device when a specific touch gesture is detected.

As mentioned above, in the OLED touch panel, the touch sensing electrodes of the touch sensor may be extremely close to the cathode layer, resulting in tremendous capacitive loading. The capacitive loading causes that the touch operations require more power consumption, which reduces the standby time of the display system 50.

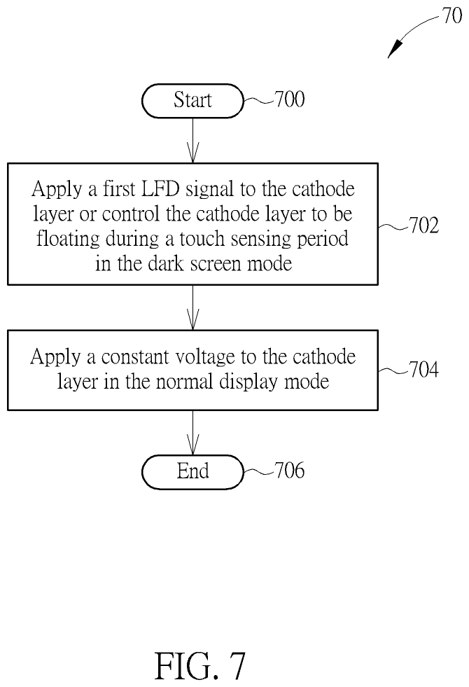

Please refer to FIG. 7, which is a flowchart of a control process 70 according to an embodiment of the present invention. The control process 70 may be realized in a touch and OLED driver such as the touch and OLED driver 502 shown in FIGS. 5 and 6, for controlling an OLED touch panel having a cathode layer of OLEDs. As shown in FIG. 7, the control process 70 includes the following steps:

Step 700: Start.

Step 702: Apply a first LFD signal to the cathode layer or control the cathode layer to be floating during a touch sensing period in the dark screen mode.

Step 704: Apply a constant voltage to the cathode layer in the normal display mode.

Step 706: End.

According to the control process 70, the touch and OLED driver 502 may apply the LFD signal to the cathode layer of the OLEDs in the OLED panel 500 during the touch sensing period in the dark screen mode. The LFD signal may be identical to the touch driving signal sent to the touch sensor. For example, the pulses of the LFD signal may have substantially identical frequency, phase, and/or amplitude as the pulses of the touch driving signal, such that the LFD signal and the touch driving/sensing signal may rise and fall concurrently. Alternatively, the touch and OLED driver 502 may control the cathode layer of the OLEDs to be floating during the touch sensing period. The floating status allows the voltage of the cathode electrode to shift upward and downward following the pulses of the touch signal due to coupling capacitors between the cathode electrode and the touch sensor. The cathode electrode may be floating when every terminal of the cathode electrode is only connected to high impedance node (s), or any external connection of the cathode electrode is cut off.

The LFD signal applied to the cathode layer when the touch signal is sent to the touch sensor may effectively cancel or reduce the capacitive loading between the cathode layer and the touch sensing electrodes. When the LFD signal identical to the touch driving signal is applied to the cathode electrode while the touch signal is sent, the voltage difference between the cathode layer and the touch sensor may keep constant since the LFD signal and the touch signal rise and fall concurrently. In such a situation, the coupling capacitors between the cathode layer and the touch sensor may not detect any variation of voltage difference, which may be equivalent to the situation where no coupling capacitors exist.

In this embodiment, the LED signal applied to the cathode layer may cancel or reduce the capacitive loading between the cathode layer and the touch sensor. Alternatively or additionally, the touch and OLED driver 502 may further apply a second LFD signal to the data lines and/or the scan lines of the OLED panel 500, and/or control the data lines and/or the scan lines of the OLED panel 500 to be floating during the touch sensing period in the dark screen mode. Please refer back to FIGS. 5 and 6, where each display pixel is coupled to a data line and a scan line, and thus there may be hundreds or thousands of data lines and scan lines coupled to all display pixels on the OLED panel 500. The data lines and scan lines may be disposed on the substrate of the OLED panel 500, such as the substrate 300 shown in FIG. 3. Therefore, these data lines and scan lines are also extremely close to the cathode layer of the panel under the structure of the OLED touch panel 30 as shown in FIG. 3, and thus there is large capacitive loading between the cathode electrode and any of the data lines and scan lines. Therefore, the data lines and scan lines may also generate non-ignorable capacitive loading on the touch sensor, resulting in more power consumption of touch sensing operations. In such a situation, it is preferable to apply the LFD signal to the data lines and/or the scan lines, or control the data lines and/or the scan lines to be floating, in order to cancel or reduce the capacitive loading.

In the embodiments of the present invention, the approaches of applying the LFD signals and floating controls may be configured flexibly. For example, there may be one or more data lines receiving the LFD signals, while other data lines are controlled to be floating; and there may be one or more scan lines receiving the LFD signals, while other scan lines are controlled to be floating. In fact, the LFD and/or floating approaches may be selectively and flexibly applied to any one or more of the cathode layer, the data lines and the scan lines, based on various factors such as the loading condition of the panel.

It should be noted that the output of the LFD signal and the floating control are applied when touch sensing is performed in the dark screen mode. These LFD and floating operations may not be feasible in the display mode; this is because the LFD signal and floating control on the cathode electrode, data line or gate line may affect the display of images. For example, if an LFD signal is applied to any of the cathode electrode, data line or gate line, a flicker may appear in the display image during the touch sensing period due to variation of the pixel voltage.

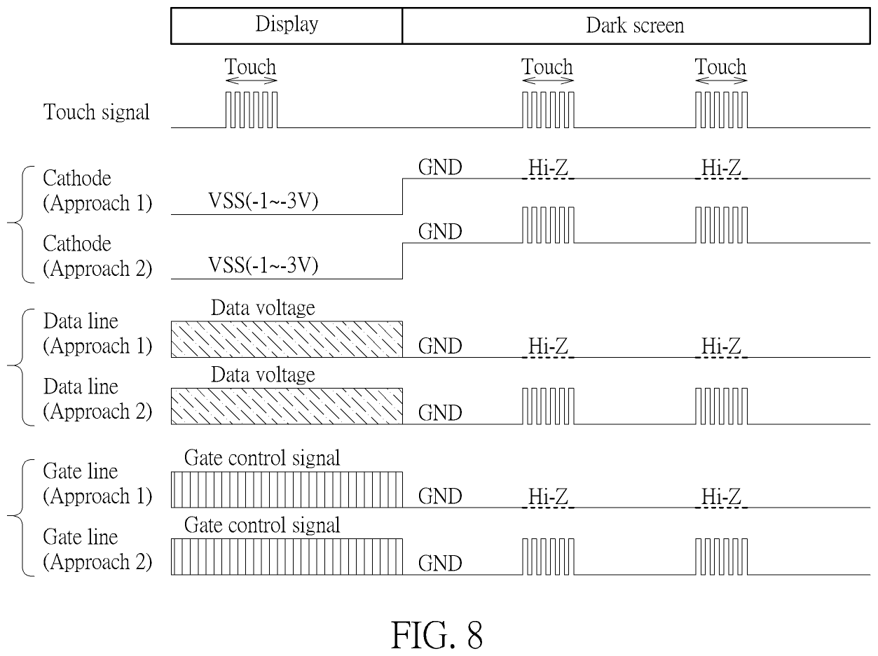

Please refer to FIG. 8, which is an exemplary waveform diagram of related signals of the display system 50. As shown in FIG. 8, the display operations include a display period and a dark screen period, where the display period may be in any type of display mode such as a normal display mode or AOD mode. The touch operation may be performed in touch sensing periods periodically appearing in both the display period and the dark screen period. In this embodiment, the touch signals (driving or sensing signals) are composed of square-wave pulses, but those skilled in the art should understand that the touch signals may be realized in other manners, such as being composed of sinusoidal-wave signals, triangular-wave pulses or trapezoidal-wave pulses.

In the display period, the cathode layer receives a negative power supply voltage VSS, which may be between −3V and −1V, as being controlled by the touch and OLED driver 502. The source line receives data voltages and forwards the data voltages to their target pixels. The gate line receives gate control signals to sequentially turn on the target pixels. As mentioned above, the LFD operation is not applied during the display period since it may affect the image display.

In the dark screen period, the cathode layer, the data line and the source line are pulled to the ground voltage (GND), so that the OLEDs on the panel may not emit light and the display function may be turned off. During the touch sensing period, the touch signal toggles with several square-wave pulses; meanwhile, the LFD signals having identical square-wave pulses may be sent to the cathode layer, the data line and/or the gate line (Approach 1), or the cathode layer, the data line and/or the gate line may be controlled to be floating (i.e., in high-impedance (Hi-Z) status) (Approach 2). As a result, the capacitive loading may be reduced with the LFD signals and/or the floating controls.

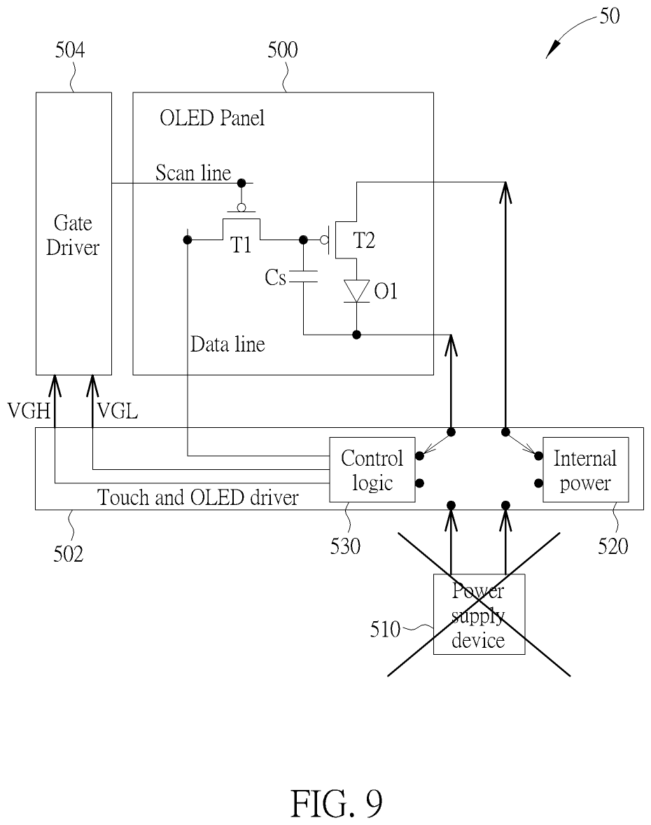

The abovementioned approaches of applying the LFD signals and floating controls may be realized with the touch and OLED driver 502. FIG. 9 shows that the cathode electrode of the OLED is coupled to the control logic 530, allowing the control logic 530 to send the LFD signal to the cathode electrode or control the cathode electrode to be floating. Similarly, the data line and/or the gate line, which are controlled by the control logic 530, may receive the LFD signal from the control logic 530 or may be floating under control of the control logic 530.

Please note that the embodiments of the present invention aim at providing a method of applying the LFD signals and/or floating controls for the cathode layer, data lines and/or gate lines of an OLED touch panel, in order to cancel or reduce capacitive loading of touch sensing operations. Those skilled in the art may make modifications and alternations accordingly. For example, the structure of the OLED display pixel described in this disclosure is merely an exemplary implementation. Those skilled in the art may understand that the approaches of applying the LFD signals and/or floating controls may be applicable to an OLED touch panel having any possible pixel structure. In addition, in the embodiments of the present invention, a touch and OLED driver may be implemented as an IC included in a chip, or may be implemented as a combination of multiple ICs. For example, the touch and OLED driver may be implemented in a touch and display driver integration (TDDI) IC, or realized with a two-chip solution having a touch control IC and a display control IC.

To sum up, the present invention may provide a control method for an OLED touch panel. In the structure of a novel on-cell OLED touch panel, the touch sensing electrodes of the touch sensor are extremely close to the cathode layer of the OLED, which generates tremendous capacitive loading, resulting in that the touch driving/sensing operation has to consume more power. In order to solve this problem, the touch and OLED driver of the present invention may apply an LFD signal to the cathode electrode, and/or control the cathode electrode to be floating. In addition, an LFD signal may be applied to the data lines and/or the gate lines of the OLED panel (or the floating control may be applied to the data lines and/or the gate lines) since there may also be large capacitive loading between the touch sensing electrodes and the data lines and/or gate lines. The LFD operations and/or floating controls may be performed during the touch sensing periods in the dark screen mode, so as to reduce the standby time of the device under dark screen without affecting the image display.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A control method for a touch and organic light-emitting diode (OLED) driver, for controlling an OLED touch panel, the OLED touch panel having a dark screen mode and a normal display mode, and comprising a cathode layer of OLEDs, the control method comprising:
applying a first load-free driving (LFD) signal to the cathode layer or controlling the cathode layer to be floating during a touch sensing period in the dark screen mode; and
applying a constant voltage to the cathode layer in the normal display mode.

2. The control method of claim 1, wherein the OLED touch panel further comprises a plurality of data lines and a plurality of scan lines, and the control method further comprises:
applying a second LFD signal to at least one line of the plurality of data lines and the plurality of scan lines or controlling at least one line of the plurality of data lines and the plurality of scan lines to be floating during the touch sensing period in the dark screen mode.

3. The control method of claim 1, wherein the dark screen mode is an operation mode in which a display function of the OLED touch panel is off.

4. The control method of claim 1, wherein the OLED touch panel further has an always on display (AOD) mode.

5. The control method of claim 4, wherein the cathode layer is coupled to an internal power source of the touch and OLED driver in the AOD mode and coupled to an external power source independent to the touch and OLED driver in the normal display mode.

6. A touch and organic light-emitting diode (OLED) driver, configured to control an OLED touch panel, the OLED touch panel having a dark screen mode and a normal display mode, and comprising a cathode layer of OLEDs, the touch and OLED driver being configured to:
apply a first load-free driving (LFD) signal to the cathode layer or control the cathode layer to be floating during a touch sensing period in the dark screen mode; and
apply a constant voltage to the cathode layer in the normal display mode.

7. The touch and OLED driver of claim 6, wherein the OLED touch panel further comprises a plurality of data lines and a plurality of scan lines, and the touch and OLED driver is further configured to:
apply a second LFD signal to at least one line of the plurality of data lines and the plurality of scan lines or controlling at least one line of the plurality of data lines and the plurality of scan lines to be floating during the touch sensing period in the dark screen mode.

8. The touch and OLED driver of claim 6, wherein the dark screen mode is an operation mode in which a display function of the OLED touch panel is off.

9. The touch and OLED driver of claim 6, wherein the OLED touch panel further has an always on display (AOD) mode.

10. The touch and OLED driver of claim 9, wherein the cathode layer is coupled to an internal power source of the touch and OLED driver in the AOD mode and coupled to an external power source independent to the touch and OLED driver in the normal display mode.
